(19) United States
(12) Patent Application Publication
(10) Pub. No.: US 2002/0177308 A1
(43) Pub. Date: Nov. 28, 2002

(54) Method for surface treatment protecting metallic surface of semiconductor structure

(75) Inventors: Hsueh-Chung Chen, Yung-Ho City (TW); Teng-Chun Tsai, Hsin-Chu City (TW); Yung-Tsung Wei, Pai-Ho Chen (TW)

Correspondence Address: LOWE HAUPTMAN, GILMAN & BERNER, LLP, Suite 310, 1700 Diagonal Road, Alexandria, VA, 22314, US

(73) Assignee: UNITED MICROELECTRONICS CORP.

(21) Appl. No.: 09/862,496

(22) Filed: May 23, 2001

(51) Int. Cl. H01L 21/44

(52) U.S. Cl. 438/687

(57) ABSTRACT

A method for surface treatment protecting a metallic semiconductor structure comprises providing a semiconductor structure with a metallic layer thereon. A protective layer on the metallic layer of the semiconductor structure and the protective layer comprises an metallic oxide layer. The present invention is particularly applied on the electrochemical copper surface of the semiconductor structure and a copper corrosion inhibitor BTA is used for formation of the protective layer. In particular, the present invention is applied on the steps of both pre and post-CMP.

### BACKGROUND OF THE INVENTION

1. Field of the Invention

The invention relates to the manufacture of ultra large scale integrated (ULSI) circuit chips in general, and more particularly to a method for surface treatment protecting copper surface of semiconductor.

2. Description of the Prior Art

It is the nature of semiconductor physics that as the feature sizes are scaled down, the performance of internal devices in integrated circuits improves in a compounded fashion. That is, the device speed as well as the functional capability improves. The overall circuit speed, however, becomes more dependent upon the propagation speed of the signals along the interconnects that connect the various devices together. With the advent of very and ultra large scale integration (VLSI and ULSI) circuits, it has therefore become even more important that the metal conductors that form the interconnections between devices as well as between circuits in a semiconductor have low resistivities for high signal propagation. Copper is often preferred for its low resistivity, as well as for resistance to electromigration and stress voiding properties.

It is observed that patterning, that is, photolithography and etching of metal layers to form the needed interconnects constitute a significant portion of the process steps of manufacturing semiconductor substrates, and it is known that both photolithography and etching are complicated processes. Furthermore, copper is very difficult to etch. This is one of the primary reasons why the current state of very large scale integration (VLSI) employ the use of aluminum for the wiring and tungsten plugs for providing the interconnection between the different levels of wiring. However, since copper has better electromigration property and lower resistivity than aluminum, it is a more preferred material for wiring and plugs than aluminum. In addition, copper has more improved electrical properties over tungsten, making copper a desirable metal for use as plugs as well. Thus, where it was relatively easy to etch aluminum or tungsten after depositing them to form lines or via plugs, substantial additional cost and time are now required to etch copper. Accordingly, chemical-mechanical polishing has become an attractive alternative to etching in removing unwanted copper.

Generally, a copper surface is formed by electro-chemical deposition in a solution containing copper sulfate. After electro-chemical deposition, the wafer is cleaned by using DI water. However, the copper surface of the wafer is susceptible to contamination of residue chemicals. On the other hand, the corrosion phenomena of between grain boundaries may be accelerated by handling the copper surface with a mechanical arm during the chemical-mechanical polishing step. Furthermore, the interval between the chemical-mechanical polishing and post cleaning, the copper surface is exposed outside and susceptible to oxidation again.

In accordance with mentions above, because of high reactivity on copper surface, it is important to prevent the copper surface from oxidation and corrosion in copper manufacture process.

### SUMMARY OF THE INVENTION

It is an object of the present invention to provide a method for surface treatment protecting metallic surface of a semiconductor structure. The metallic surface of the semiconductor structure is protected from oxidation and corrosion of grain boundary resulting from chemical residue.

It is another object of the present invention to provide a method for surface treatment protecting copper surface of the wafer. In the present invention, a metallic oxide layer is formed on the copper surface through reaction of corrosion inhibitor and the copper surface.

In the present invention, a method for surface treatment protecting a metallic semiconductor structure comprises providing a semiconductor structure with a metallic layer thereon. A protective layer on the metallic layer of the semiconductor structure and the protective layer comprises an metallic oxide layer. The present invention is particularly applied on the electro-chemical copper surface of the semiconductor structure.

### BRIEF DESCRIPTION OF THE DRAWINGS

A better understanding of the invention may be derived by reading the following detailed description with reference to the accompanying drawing wherein:

FIG. 1 is a schematic diagram illustrating the modification of a chemical-mechanical polishing equipment for the present invention; and

FIG.2 is an another schematic diagram illustrating the modification of the chemical-mechanical polishing equipment for the present invention.

### DESCRIPTION OF THE PREFERRED EMBODIMENT

The semiconductor devices of the present invention are applicable to a board range of semiconductor devices and can be fabricated from a variety of semiconductor materials. While the invention is described in terms of a single preferred embodiment, those skilled in the art will recognize that many steps described below can be altered and that species and types of substrate and dopant as well as other materials substitutions can be freely made without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, a method for surface treatment protecting a semiconductor structure with a metallic surface comprises providing a wafer with a metallic layer thereon. The existence of the wafer is sensed and thereby treating surface of the wafer with an inhibitor-contained solution. Then the protective layer is formed by reaction of the inhibitor and the metallic layer.

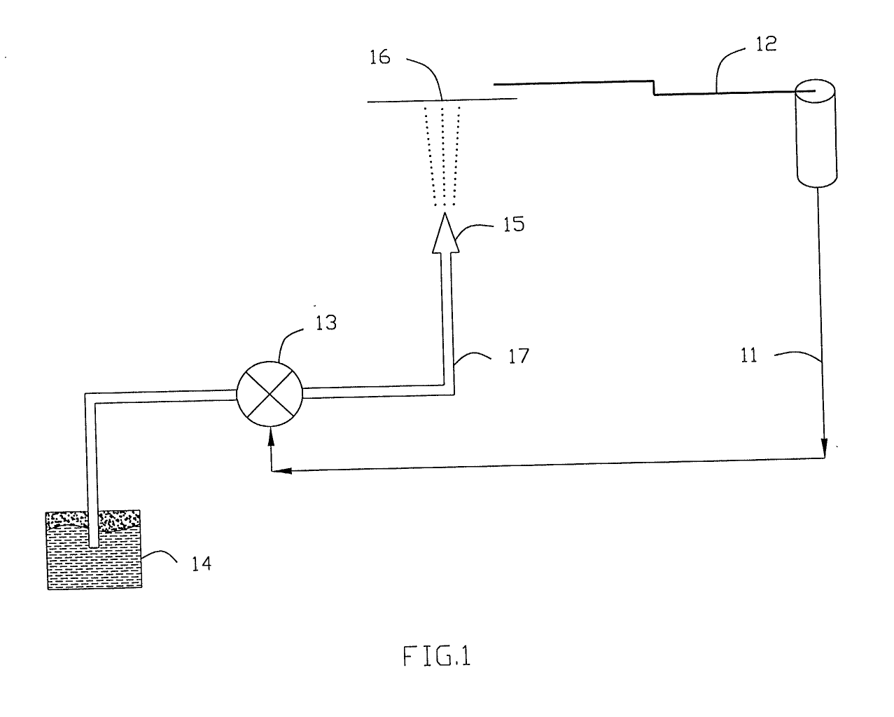

FIG. 1 shows a schematic diagram illustrating accomplishing the formation of a protective layer on the copper surface of wafer with the modification of a conventional equipment for the chemical-mechanical polishing. First, electrical signal response 11 to the mechanical arm 12 for handling the wafer in the polishing equipment is used for controlling a motor 13. The motor 13 is used for controlling a solution entrance from a tank 14 to a terminal 15. When the electrical signal response 11 senses a wafer 16 held by the mechanical arm 12 and is sent out to the motor 13, the motor 13 begins running for transporting the BTA(benzotriazole)-contained solution. The BTA-contained solution stored in the tank 14 is used for formation of a protective layer on the electro-chemical deposited copper surface of the wafer 16. Through a pipe 17 and the motor 13, the BTA-contained solution flows from the tank 14 to the terminal 15, such as a nozzle. Then the BTA-contained solution is spread on and wets the copper surface of the wafer 16 to form the protective layer, such as an oxide layer.

In the embodiment, the BTA has a concentration in BTPA-contained solution in the range of from about 0.1 g/l to about 10.0 g/l under consideration of BTA solvability. The solvent of the BTPA-contained solution is water. The oxide layer formed by the reaction of BTA and copper surface has such a tight structure that can prevent the copper surface of the wafer from further oxidation and corrosion. On the other hand, the oxide layer on the copper surface of the wafer can protect the copper surface against further chemical attack. Furthermore, the volume of BTA-contained solution spread on the copper surface of the wafer is adjustable only to wet the whole copper surface.

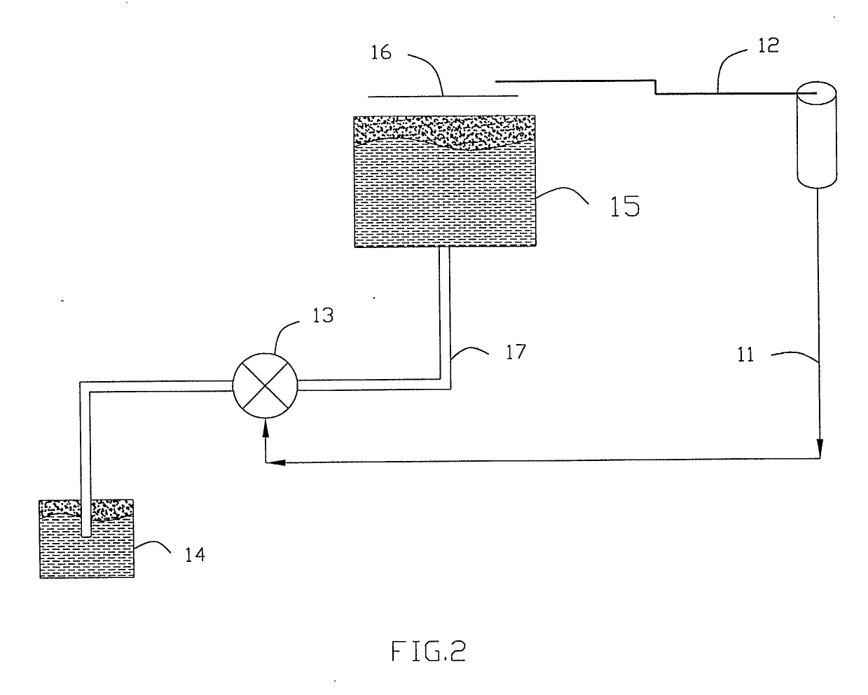

FIG. 2 is an another method for wetting the copper surface with BTA-contained solution in accordance with the present invention. The terminal 15 is an another tank containing the BTA-contained solution to let the whole wafer dipping in by operation of the mechanical arm 12. However, when BTA is used for formation of the protective layer on the copper surface in the embodiment, it is appreciated that any copper corrosion inhibitor as BTA can be used in the present invention only to adjust the concentration of the water solution. On the other hand, the formation of the protective layer in the present invention can be applied on many copper manufacture steps, such as pre-CMP, post-CMP, and so on. In particular, the formation of the protective layer is easily removed in post-clean CMP step and doesn't result in cleaning problem.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for surface treatment protecting a metallic semiconductor structure, said method comprising:
providing a semiconductor structure with a metallic layer thereon; and
forming a protective layer on said metallic layer of said semiconductor structure, said protective layer comprising an metallic oxide layer.

2. The method according to claim 1, wherein said metallic layer comprises a copper layer.

3. The method according to claim 2, wherein said copper layer is formed by using electro-chemical deposition.

4. The method according to claim 1, wherein said forming step comprises:
sensing existence of a wafer comprising said semiconductor structure;
treating surface of said wafer with an inhibitor-contained solution; and
forming said protective layer with reaction of said inhibitor and said metallic layer.

5. The method according to claim 4, wherein said inhibitor-contained solution comprises benzotriazole-contained solution.

6. The method according to claim 5, wherein said benzotriazole-contained solution has a benzotriazole concentration in range from about 0.1 g/l to about 10.0 g/l.

7. The method according to claim 4, wherein said sensing step is accomplished with reading-out an electrical signal response to handling said wafer.

8. The method according to claim 4, wherein said treating step is accomplished with spreading said inhibitor-contained solution from a nozzle.

9. The method according to claim 4, wherein said treating step is accomplished with dipping said wafer into a tank that said inhibitor-contained solution is stored.

10. A method for surface treatment protecting a wafer with a metallic surface, said method comprising:
providing a wafer with a metallic layer thereon;
sensing existence of said wafer;
treating surface of said wafer with an inhibitor-contained solution; and
forming said protective layer by reaction of said inhibitor and said metallic layer.

11. The method according to claim 10, wherein said metallic layer comprises a copper layer formed by using electro-chemical deposition.

12. The method according to claim 10, wherein said inhibitor-contained solution comprises benzotriazole-contained solution.

13. The method according to claim 12, wherein said benzotriazole-contained solution has a benzotriazole concentration in range from about 0.1 g/l to about 10.0 g/l.

14. The method according to claim 10, wherein said sensing step is accomplished with reading-out electrical signal response to handling said wafer.

15. The method according to claim 10, wherein said treating step is accomplished with spreading said inhibitor-contained solution from a nozzle.

16. The method according to claim 10, wherein said treating step is accomplished with dipping said wafer into a tank that said inhibitor-contained solution is stored.

17. The method according to claim 10, wherein said protective layer is used for prevent said wafer from oxidation and corrosion with a tight structure formation of a metallic oxide layer.
